(19) United States
(12) Patent Application Publication
(10) Pub. No.: US 2025/0293159 A1
(43) Pub. Date: Sep. 18, 2025

(54) SEMICONDUCTOR DEVICE

(71) Applicant: SK hynix Inc., Icheon-si (KR)

(72) Inventor: Kyung Wan KIM, Icheon-si (KR)

(21) Appl. No.: 18/775,837

(22) Filed: Jul. 17, 2024

(30) Foreign Application Priority Data
Mar. 12, 2024 (KR) 10-2024-0034391

(51) Int. Cl. H01L 23/528; H10B 63/00

(52) U.S. Cl. CPC H01L 23/5283; H10B 63/80

(57) ABSTRACT

A semiconductor device includes: a plurality of pairs of tile regions arranged in a first direction and a second direction crossing the first direction; a first switching region disposed on a first side of the first tile region in the first direction and disposed beside a second sub-region of the first tile region; a first conductive line extending in the first direction to cross the first switching region and tile regions, and electrically connected to the first switching region; a second conductive line extending in the second direction to cross each pair of tile regions and the second switching region, and electrically connected to the second switching region; and a memory cell disposed in an intersection region between the first conductive line and the second conductive line in a third direction that is perpendicular to the first and second directions.

### CROSS-REFERENCE TO RELATED APPLICATIONS

The present application claims priority under 35 U.S.C 119(a) to Korean Patent Application No. 10-2024-0034391, filed on Mar. 12, 2024, in the Korean Intellectual Property Office, which is incorporated herein by reference in its entirety.

### BACKGROUND

### 1. Field

Embodiments of the present disclosure relate to a semiconductor technology, and more particularly, to a semiconductor device having a cross-point structure in which memory cells are disposed between a lower conductive line and an upper conductive line that intersect with each other.

### 2. Description of the Related Art

Recent trends for miniaturization, low-power consumption, high performance, and diversification of electronic devices require semiconductor devices that may store data in diverse electronic devices, such as computers and portable communication devices, and researchers and the industry are studying to develop such semiconductor devices. Such semiconductor devices include semiconductor devices that may store data by using the characteristic of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device that prevents defects in near memory cells and reduce the difference in operation characteristics between near memory cells and far memory cells.

Embodiments of the present disclosure are directed to a semiconductor device capable of increasing integration by reducing the number of switching regions in which contact plugs are disposed.

In accordance with an embodiment of the present invention, a semiconductor device includes: a plurality of pairs of tile regions arranged in a first direction and a second direction crossing the first direction, each pair of tile regions including first and second tile regions with a second switching region interposed therebetween in the second direction; a first switching region disposed on a first side of the first tile region in the first direction and disposed beside a second sub-region of the first tile region, the first tile region being divided into a first sub-region and the second sub-region in the second direction, the first sub-region being closer to the second switching region compared to the second sub-region; a first conductive line extending in the first direction to cross the first switching region and tile regions disposed on each of both sides of the first switching region in the first direction, and electrically connected to the first switching region; a second conductive line extending in the second direction to cross each pair of tile regions and the second switching region, and electrically connected to the second switching region; and a memory cell disposed in an intersection region between the first conductive line and the second conductive line in a third direction that is perpendicular to the first and second directions.

In accordance with another embodiment of the present invention, a semiconductor device includes: first and second tile regions including a plurality of first conductive lines each extending in a first direction, a plurality of second conductive lines each extending in a second direction crossing the first direction, and a plurality of memory cells respectively overlapping with intersection regions between the first conductive lines and the second conductive lines, the first and second tile regions being disposed to be adjacent to each other in the second direction; a second switching region disposed between the first tile region and the second tile region and coupled to the second conductive lines; and a first switching region disposed on a first side of the first tile region in the first direction, and coupled to a first conductive line crossing a second sub-region of the first tile region, wherein the first tile region is divided into a first sub-region and the second sub-region in the second direction, the first sub-region being closer to the second switching region compared to the second sub-region.

### BRIEF DESCRIPTION OF THE DRAWINGS

FIGS. 1A to 1D illustrate a semiconductor device in accordance with an embodiment of the present disclosure.

FIG. 1E is a cross-sectional view illustrating a memory cell in accordance with an embodiment of the present disclosure.

FIG. 1F is a cross-sectional view illustrating a memory cell in accordance with another embodiment of the present disclosure.

FIG. 1G numerically illustrate the distance from a switching region to a memory cell in the semiconductor device shown in FIGS. 1A to 1D.

FIGS. 2A and 2B illustrate a semiconductor device in accordance with another embodiment of the present disclosure.

FIG. 2C numerically illustrate the distance from a switching region to a memory cell in the semiconductor device shown in FIGS. 2A and 2B.

### DETAILED DESCRIPTION

Hereinafter, embodiments of the present disclosure will be described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly over the second layer or the substrate but also a case where a third layer exists between the first layer and the second layer or the substrate.

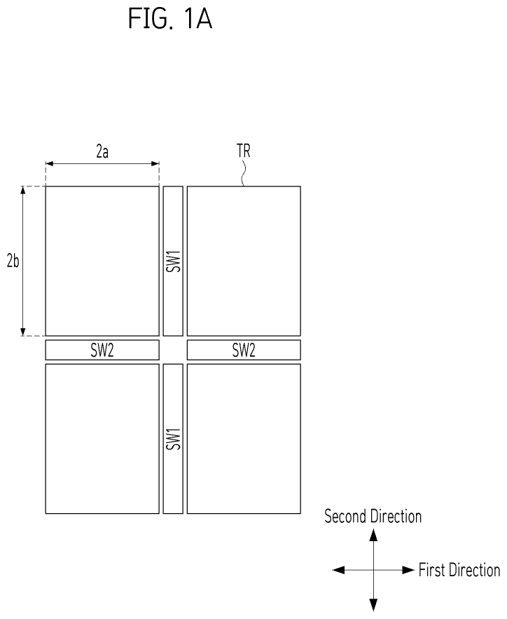

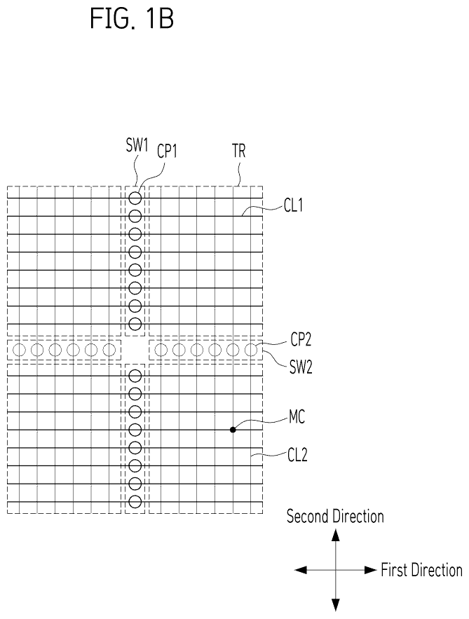

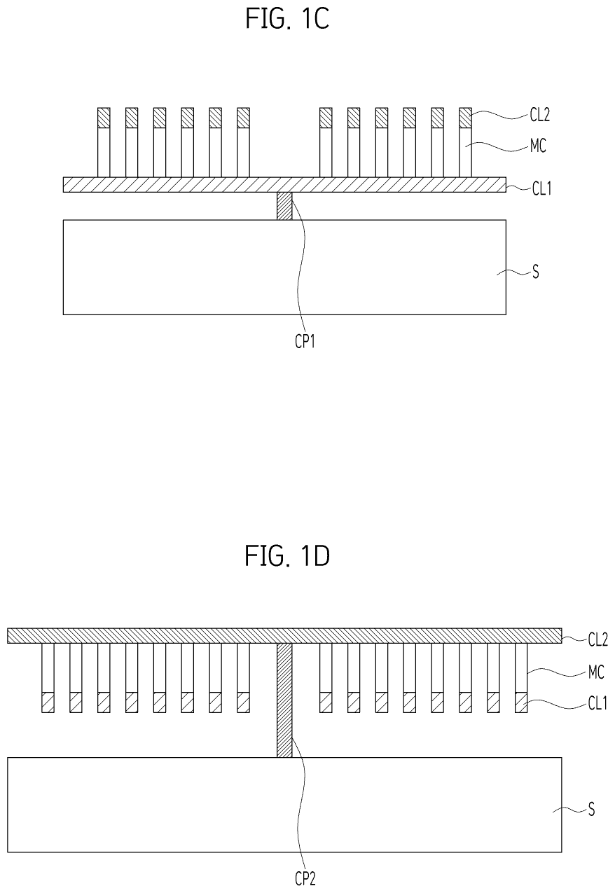

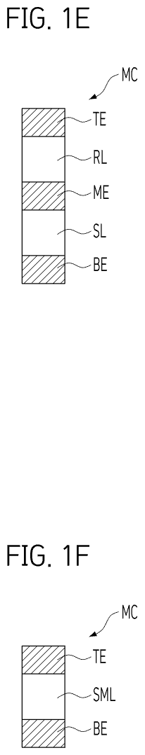

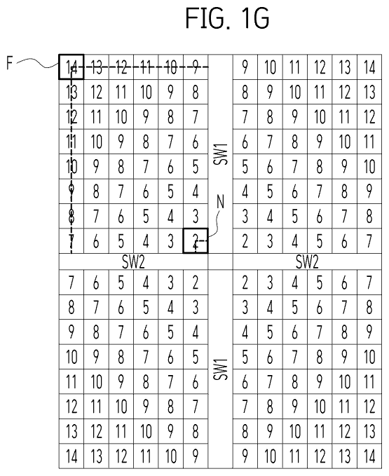

FIGS. 1A to 1D illustrate a semiconductor device in accordance with an embodiment of the present disclosure. To be specific, FIG. 1A is a plan view schematically illustrating a tile region and a switching region of the semiconductor device, and FIG. 1B is a plan view illustrating a conductive line, a memory cell, and a contact plug that are arranged in the tile region and the switching region. FIG. 1C is a cross-sectional view taken along a first direction shown in FIG. 1B, and FIG. 1D is a cross-sectional view taken along a second direction shown in FIG. 1B.

Referring to FIGS. 1A to 1D, the semiconductor device may include a substrate S, a plurality of first conductive lines CL1 disposed over the substrate S and extending in a first direction, a plurality of second conductive lines CL2 disposed over the first conductive line CL1 and extending in a second direction crossing the first direction, a plurality of memory cells MC disposed between the first conductive lines CL1 and the second conductive lines CL2 in a third direction to overlap with intersection regions between the first conductive lines CL1 and the second conductive lines CL2, a first contact plug CP1 disposed between each of the first conductive lines CL1 and the substrate S and electrically connecting each of the first conductive lines CL1 to a portion of the substrate S, and a second contact plug CP2 disposed between each of the second conductive lines CL2 and the substrate S and electrically connecting each of the second conductive lines CL2 to a portion of the substrate S. Here, the first direction and the second direction may correspond to a horizontal direction which is substantially parallel to a top surface of the substrate S. The third direction may correspond to a vertical direction which is substantially perpendicular to the first and second directions. In this figure, the first direction is illustrated to correspond to an X-axis, and the second direction is illustrated to correspond to a Y-axis, but the concept and spirit of the present invention are not limited thereto. The first direction and the second direction may be modified diversely based on the precondition that they intersect with each other. Hereinafter, the term “plane” may refer to a surface defined by the first direction and the second direction.

The semiconductor device or the substrate S in accordance with this embodiment of the present disclosure may include a plurality of tile regions TR, a plurality of first switching regions SW1, and a plurality of second switching regions SW2 from the perspective of a plan view. A tile region TR may correspond to a region where a plurality of memory cells MC are arranged at the intersections of first conductive lines CL1 and second conductive lines CL2. A first switching region SW1 may correspond to a region where first contact plugs CP1 coupled to the first conductive lines CL1 are arranged, intersecting with the first conductive lines CL1. A second switching region SW2 may correspond to a region where second contact plugs CP2 coupled to the second conductive lines CL2 are arranged, intersecting with the second conductive lines CL2. According to this embodiment of the present disclosure, four tile regions TR may be arranged in a 2*2 form in the first direction and the second direction, and a first switching region SW1 may be arranged between two tile regions TR that are adjacent to each other in the first direction, and a second switching region SW2 may be disposed between two tile regions TR that are adjacent to each other in the second direction. The four tile regions TR, two first switching regions SW1, and two second switching regions SW2 arranged as described above may form one mat. Although not illustrated, in the semiconductor device, a plurality of mats may be arranged in the first direction and the second direction from the perspective of a plan view.

The substrate S may include a semiconductor material such as silicon. A required predetermined lower structure (not shown) may be formed in the substrate S. For example, a driving circuit electrically connected to the first contact plug CP1 to drive the first conductive line CL1, and a driving circuit electrically connected to the second contact plug CP2 to drive the second conductive line CL2 may be disposed in the substrate S.

The first conductive lines CL1 may extend in the first direction to be spaced apart from each other in the second direction. In the first direction, the first conductive line CL1 may cross two tile regions TR and the first switching region SW1 disposed between the two tile regions TR. Accordingly, the center of the first conductive line CL1 may contact the first contact plug CP1 disposed in the first switching region SW1. When the length of one tile region TR in the first direction is ‘2a,’ the length of a portion of the first conductive line CL1 disposed on each side of the first switching region SW1 in the first direction may be substantially the same as 2a.

According to this embodiment of the present disclosure, the number of first conductive lines CL1 crossing one tile region TR is 8. However, embodiments are not limited thereto, and the number of first conductive lines CL1 crossing one tile region TR may vary. The first conductive lines CL1 may include a conductive material, such as a metal like platinum (Pt), tungsten (W), aluminum (Al), copper (Cu), tantalum (Ta), or titanium (Ti); a metal nitride like titanium nitride (TiN) or tantalum nitride (TaN); or a combination thereof.

The second conductive lines CL2 may extend in the second direction to be spaced apart from each other in the first direction. In the second direction, the second conductive line CL2 may cross two tile regions TR and the second switching region SW2 disposed between the two tile regions TR. Accordingly, the center of the second conductive line CL2 may contact the second contact plug CP2 disposed in the second switching region SW2. When the length of one tile region TR in the second direction is ‘2b,’ the length of a portion of the second conductive line CL2 disposed on each side of the second switching region SW2 in the second direction may be substantially the same as 2b. According to this embodiment of the present disclosure, the number of second conductive lines CL2 crossing one tile region TR is 6. However, embodiments are not limited thereto, and the number of second conductive lines CL2 crossing one tile region TR may vary.

According to this embodiment of the present disclosure, 2a and 2b may be different, and accordingly, the number of first conductive lines CL1 crossing one tile region TR and the number of second conductive lines CL2 crossing one tile region TR may be different. However, embodiments are not limited thereto. According to another embodiment, 2a and 2b may be substantially the same, and accordingly, the number of first conductive lines CL1 crossing one tile region TR and the number of second conductive lines CL2 crossing one tile region TR may be the same. The second conductive lines CL2 may include a conductive material, such as a metal like platinum (Pt), tungsten (W), aluminum (Al), copper (Cu), tantalum (Ta), or titanium (Ti); a metal nitride like titanium nitride (TiN), or tantalum nitride (TaN); or a combination thereof.

The first contact plugs CP1 may be disposed in the first switching region SW1 to be respectively coupled to the first conductive lines CL1. Accordingly, the first contact plugs CP1 may be arranged in the second direction. The number of first contact plugs CP1 arranged in the first switching region SW1 may be the same as the number of first conductive lines CL1 crossing one tile region TR. For example, eight first contact plugs CP1 may be arranged in the first switching region SW1. The first contact plug CP1 may have a pillar shape, and may include a conductive material, such as a metal like platinum (Pt), tungsten (W), aluminum (Al), copper (Cu), tantalum (Ta), or titanium (Ti); a metal nitride like titanium nitride (TiN), or tantalum nitride (TaN); or a combination thereof.

The second contact plugs CP2 may be disposed in the second switching region SW2 to be respectively coupled to the second conductive lines CL2. Accordingly, the second contact plugs CP2 may be arranged in the first direction. The number of second contact plugs CP2 arranged in the second switching region SW2 may be the same as the number of second conductive lines CL2 crossing one tile region TR. For example, when six second conductive lines CL2 cross one tile region TR, six second contact plugs CP2 may be arranged in the second switching region SW2. The second contact plug CP2 may have a pillar shape, and may include a conductive material, such as a metal like platinum (Pt), tungsten (W), aluminum (Al), copper (Cu), tantalum (Ta), or titanium (Ti); a metal nitride like titanium nitride (TiN) or tantalum nitride (TaN); or a combination thereof.

The memory cells MC may be arranged to overlap with the intersection regions between the first conductive lines CL1 and the second conductive lines CL2, forming a matrix in the first and second directions in the tile region TR. For example, 48 memory cells MC may be arranged in a 6*8 configuration in one tile region TR in the first and second directions. The memory cell MC may have a pillar shape. As long as the memory cells MC have the function of storing data, the data storage method, the materials forming the memory cells MC, and the layer structure of the memory cells MC may vary. For example, the memory cells MC may include a variable resistance layer that stores different data by switching between different resistance states according to the voltage or current applied thereto through the first conductive line CL1 and the second conductive line CL2. Examples of the memory cells MC will be further described with reference to FIGS. 1E and 1F.

FIG. 1E is a cross-sectional view illustrating a memory cell in accordance with an embodiment of the present disclosure.

Referring to FIG. 1E, the memory cell MC may include a stacked structure of a bottom electrode layer BE, a selector layer SL, a middle electrode layer ME, a variable resistance layer RL, and a top electrode layer TE.

The bottom electrode layer BE and the top electrode layer TE may be disposed at both ends of the memory cell MC, that is, at the bottom and top ends, respectively, and may function to transfer the voltage or current required for an operation of the memory cell MC. The middle electrode layer ME may serve to electrically connect the selector layer SL and the variable resistance layer RL while physically separating them from each other. The bottom electrode layer BE, the middle electrode layer ME, or the top electrode layer TE may include a conductive material, such as a metal like platinum (Pt), tungsten (W), aluminum (Al), copper (Cu), tantalum (Ta), or titanium (Ti); a metal nitride like titanium nitride (TiN) or tantalum nitride (TaN); or a combination thereof. The bottom electrode layer BE, the middle electrode layer ME, or the top electrode layer TE may include a carbon electrode.

The selector layer SL may control access to the variable resistance layer RL and prevent potential current leakage between the memory cells MC that share the first conductive line CL1 or the second conductive line CL2. To this end, the selector layer SL may have threshold switching characteristics, meaning it blocks or reduces current flow when the voltage supplied to the top and bottom ends of the selector layer SL is lower than a predetermined threshold voltage. However, it enables rapid current flow when the voltage level is equal to or higher than the threshold voltage. In other words, the selector layer SL may be activated when the voltage level is equal to or higher than the threshold voltage and deactivated when the voltage level is lower than the threshold voltage.

The selector layer SL may include any of various materials such as Ovonic Threshold Switching (OTS) materials like diodes and chalcogenide-based materials, Mixed Ionic Electronic Conducting (MIEC) materials like metal-containing chalcogenide-based materials, Metal Insulator Transition (MIT) materials like NbO₂ and VO₂, or tunneling dielectric materials with relatively wide band gaps like SiO₂ and Al₂O₃.

The selector layer SL may include a dielectric material doped with an ion implanted dopant. Here, the dielectric material may include a silicon-containing dielectric material, such as silicon oxide, silicon nitride, silicon oxynitride, or similar compounds, a dielectric metal oxide, a dielectric metal nitride, or a combination thereof. The dopant may serve to create trap sites that capture conductive carriers moving in the dielectric material or facilitate a pathway for the captured conductive carriers to move once again. To create the trap sites, various elements capable of generating energy potentials that can accommodate the conductive carriers in the dielectric material may be used as dopants.

For example, when the dielectric material includes a silicon-containing dielectric material, the dopant may include a metal with a valence different from silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof.

When the dielectric material includes a dielectric metal oxide or a dielectric metal nitride, the dopant may include silicon, or a metal with a valence different from that of the metal in the dielectric metal oxide or the dielectric metal nitride.

For example, the selector layer SL may include silicon dioxide (SiO₂) that is doped with arsenic (As). When a voltage equal to or higher than the threshold voltage is applied to the selector layer SL, the conductive carriers may move through the trap sites, achieving an “on” state in which current flows through the selector layer SL. Conversely, when the voltage applied to the selector layer SL is reduced to be lower than the threshold voltage, the conductive carriers remain stationary, resulting in an “off” state in which no current flows.

The variable resistance layer RL may be a part of the memory cell MC that functions to store data. To this end, the variable resistance layer RL may have variable resistance characteristics of switching between different resistance states according to the applied voltage. The variable resistance layer RL may have a single-layer structure or a multi-layer structure including any of various materials used in a Resistive Random Access Memory (RRAM), a Phase-change Random Access Memory (PRAM), a Ferroelectric Random Access Memory (FRAM), a Magnetic Random Access Memory (MRAM), and the like. The variable resistance layer RL may include any of materials such as metal oxides (e.g., transition metal oxides, perovskite-based materials, or the like), phase-change materials (e.g., chalcogenide materials or the like), ferroelectric materials, ferromagnetic materials, or the like. When the variable resistance layer RL has a high resistance state, the memory cell MC may store, for example, data ‘0,’ and when the variable resistance layer RL has a low resistance state, the memory cell MC may store, for example, data ‘1.’

However, the layer structure of the memory cell MC is not limited to that illustrated in FIG. 1E. The stacking order of the layers may be changed, or one or more of the layers may be omitted, or one or more additional layers may be added. For example, one or more of the bottom electrode layer BE, the middle electrode layer ME, and the top electrode layer TE may be omitted. Additionally, the positions of the selector layer SL and the variable resistance layer RL may be reversed. In other words, the selector layer SL may be disposed over the middle electrode layer ME, and the variable resistance layer RL may be disposed below the middle electrode layer ME. One or more additional layers (not shown) may be added to the memory cell MC to improve the process or the characteristics of the memory cell MC.

FIG. 1F is a cross-sectional view illustrating a memory cell in accordance with another embodiment of the present disclosure.

Referring to FIG. 1F, the memory cell MC may include a stacked structure of a bottom electrode layer BE, a self-selecting memory layer SML, and a top electrode layer TE.

The self-selecting memory layer SML may be a layer that simultaneously performs the function of a memory element and a selection element, and it may also be referred to as a dual function material (DFM). To be specific, the self-selecting memory layer SML may have variable resistance characteristics, allowing it to store different data by switching between different resistance states according to the voltage applied to the bottom electrode layer BE and the top electrode layer TE. At the same time, the self-selecting memory layer SML may have threshold switching characteristics, allowing minimal current flow when the applied voltage is lower than a predetermined threshold voltage, and then permitting rapid current flow when the applied voltage is equal to or higher than the threshold voltage. The predetermined threshold voltage, referred to as a threshold voltage, determines the activation or deactivation of the self-selecting memory layer SML, effectively turning it on or off.

Here, the threshold voltage of the self-selecting memory layer SML may vary depending on its resistance state. In other words, different resistance states of the self-selecting memory layer SML may correspond to different threshold voltages. For example, when the self-selecting memory layer SML is in a low-resistance state, it may have a first threshold voltage. Conversely, when the self-selecting memory layer SML is in a high-resistance state, it may have a second threshold voltage that is different from the first threshold voltage. This allows for the simultaneous realization of both memory and selection functions in a single self-selecting memory layer SML.

Although not illustrated, a memory cell may be structured around an electrode or a conductive line, typically arranged in the form of a single vertical column. The memory cell according to this embodiment of the present disclosure may include a structure of a first electrode layer, a self-selecting memory layer surrounding the first electrode layer, and a second electrode layer surrounding the self-selecting memory layer. Since the method of operating the device has been described above, additional details will be omitted.

Meanwhile, the distance between the memory cell MC in the tile region TR and the switching regions SW1 and SW2 may vary depending on their respective locations. This will be illustrated with reference to FIG. 1G.

FIG. 1G numerically illustrates the distance from a switching region to a memory cell in the semiconductor device shown in FIGS. 1A to 1D.

Referring to FIG. 1G, the numbers may represent the distance of each of 48 memory cells MC disposed in each tile region TR from the first and second switching regions SW1 and SW2. Here, the distance from the first and second switching regions SW1 and SW2 may be the sum of the distance from the first switching region SW1 in the first direction and the distance from the second switching region SW2 in the second direction. The distance of each memory cell MC coupled to the closest second conductive line CL2 from the first switching region SW1 in the first direction may be defined as 1, and the distance of each memory cell MC coupled to the closest first conductive line CL1 from the second switching region SW2 in the second direction may be defined as 1.

In this case, the minimum value of the distance from the first and second switching regions SW1 and SW2 to the memory cell MC may correspond to 1+1, that is, 2. In other words, the distance to the memory cell MC represented by N may correspond to 2. On the other hand, the maximum value of the distance from the first and second switching regions SW1 and SW2 to the memory cell MC may be 6+8, that is, 14. In other words, the distance to the memory cell MC represented by F may be 14. In a similar manner, the distance of each of the memory cells MC from the first and second switching regions SW1 and SW2 may be calculated as illustrated in FIG. 1G.

A memory cell MC positioned relatively close to the first and second switching regions SW1 and SW2 may be referred to as a “near memory cell,” and a memory cell MC positioned relatively farther away from the first and second switching regions SW1 and SW2 may be referred to as a “far memory cell.” The criterion for determining the near memory cell and the far memory cell may vary. For example, memory cells MC positioned at a distance equal to or less than 5 from the first and second switching regions SW1 and SW2 may be referred to as “near memory cells,” whereas memory cells MC positioned more than 5 units away from the first and second switching regions SW1 and SW2 may be referred to as “far memory cells.”

To ensure normal operations of both near memory cells and far memory cells, a relatively high voltage or current might need to be supplied to the first and second conductive lines CL1 and CL2. However, this approach can result in an excessive current, such as an overshooting current or a spike current, flowing into the near memory cells, potentially causing operational failures in the near memory cells. Moreover, as the difference between the distance between the first and second switching regions SW1 and SW2 and the near memory cells and the distance between the first and second switching regions SW1 and SW2 and the far memory cells increases, the disparity in the operation characteristics of the near and far memory cells becomes more pronounced. This may lead to a deterioration in the overall operation characteristics of the semiconductor device.

Hereinafter, a semiconductor device is described that may improve operation characteristics by preventing or reducing operational failures in near memory cells. This is achieved by reducing the difference between the distance between the first and second switching regions SW1 and SW2 and the near memory cells and the distance between the first and second switching regions SW1 and SW2 and the far memory cells.

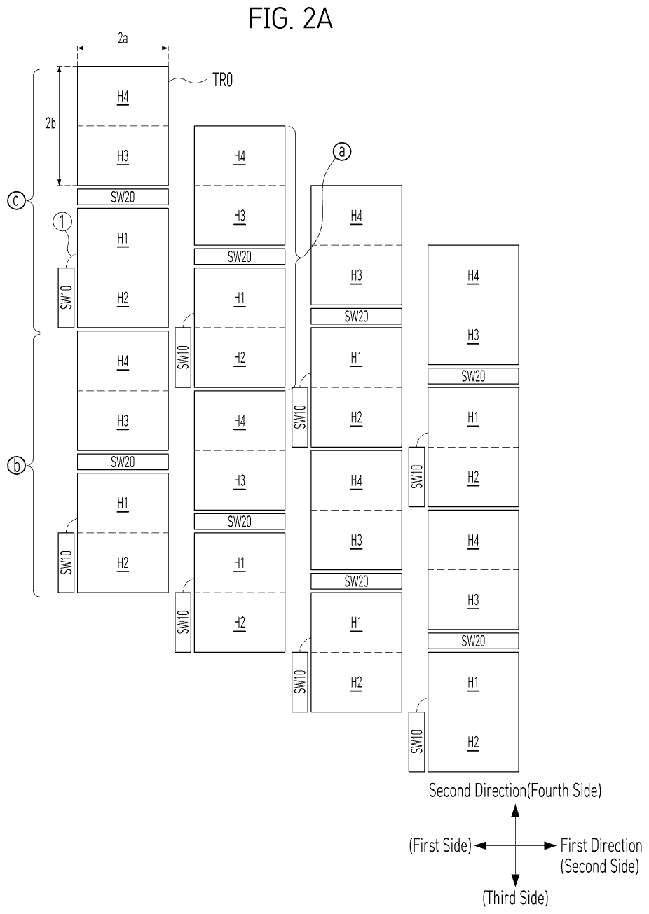

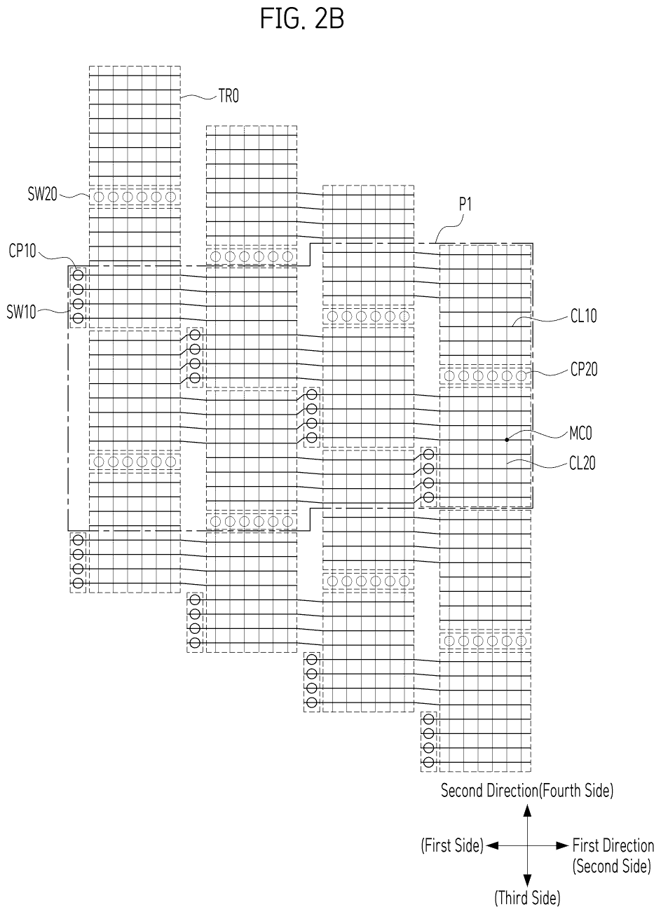

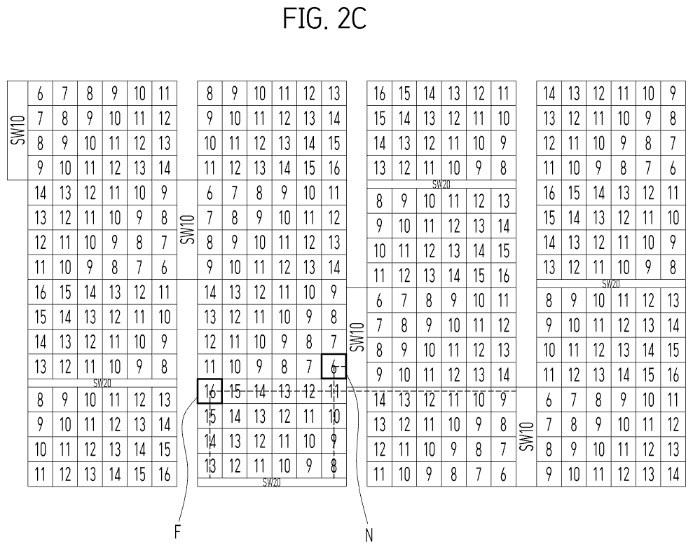

FIGS. 2A and 2B illustrate a semiconductor device in accordance with another embodiment of the present disclosure. To be specific, FIG. 2A is a plan view briefly illustrating a tile region and a switching region of the semiconductor device, and FIG. 2B is a plan view illustrating conductive lines, memory cells, and contact plugs that are arranged in the tile region and the switching region. Detailed description of the components that are substantially the same as those in the above-described embodiment will be omitted. The following description will focus on the differences from the above-described embodiment of the present disclosure.

Referring to FIGS. 2A and 2B, the semiconductor device may include a plurality of first conductive lines CL10 disposed over a substrate and extending in the first direction, a plurality of second conductive lines CL20 disposed over the first conductive lines CL10 and extending in the second direction crossing the first direction, a plurality of memory cells MC0 respectively overlapping with intersection regions between the first conductive lines CL10 and the second conductive lines CL20, a first contact plug CP10 electrically connecting each of the first conductive lines CL10 to a portion of the substrate and disposed between the first conductive line CL10 and the substrate, and a second conductive plug CP20 electrically connecting each of the second conductive lines CL20 to a portion of the substrate and disposed between the second contact line CL20 and the substrate.

The semiconductor device or substrate may include tile regions TR0, first switching regions SW10, and second switching regions SW20 from the perspective of a plan view. A tile region TR0 may correspond to a region where a plurality of memory cells MC0 are arranged between corresponding first conductive lines CL10 and corresponding second conductive lines CL20. A first switching region SW10 may correspond to a region where first contact plugs CP10 coupled to corresponding first conductive lines CL10 are arranged. A second switching region SW20 may correspond to a region where second contact plugs CP20 coupled to corresponding second conductive lines CL20 are arranged.

The second switching region SW20 may be disposed between two adjacent tile regions TR0 in the second direction. Hereinafter, the two adjacent tile regions TR0 in the second direction, with the second switching region SW20 between them, will be referred to as a pair of tile regions TR0.

Hereinafter, for the sake of convenience in description, both sides in the first direction may be referred to as a first side and a second side, respectively, and both sides in the second direction may be referred to as a third side and a fourth side, respectively. According to this embodiment, with respect to the orientation of FIG. 2A or 2B, the first side and the second side correspond to the left side and the right side, respectively, and the third side and the fourth side correspond to the lower side and the upper side, respectively. However, embodiments are not limited thereto. According to another embodiment, the first side and the second side may correspond to the right side and the left side, respectively, and the third side and the fourth side may correspond to the lower side and the upper side, or the upper side and the lower side, respectively.

The first switching region SW10 may be disposed on the first side of one tile region among two adjacent tile regions TR0 in a pair. Although this embodiment illustrates a case where the first switching region SW10 is disposed on the first side of the lower tile region TR0 among the two adjacent tile regions TR0 in the pair, embodiments are not limited thereto. According to another embodiment, the first switching region SW10 may be disposed on the first side of the upper tile region TR0 among the two adjacent tile regions TR0 in the pair. As described above, the first side may correspond to either the left side or the right side. Hereinafter, it is assumed that the tile region TR0, which includes the first switching region SW10 disposed on its first side, among the two adjacent tile regions TR0 in the pair, corresponds to the first switching region SW10 disposed on the first side of the tile region TR0 (see \textcircled{1} in FIG. 2A). In the pair, the tile region TR0 corresponding to the first switching region SW10 will be referred to as a first tile region, and the other tile region TR0, which includes no first switching region SW10 disposed on its first side, will be referred to as a second tile region.

The first tile region TR0 may be divided into two parts in the second direction. Each of the two parts may correspond to approximately half of the first tile region TR0. When the two parts correspond to a first sub-region H1 and a second sub-region H2, respectively, the first sub-region H1 may be closer to the second switching region SW20 compared to the second sub-region H2. The first switching region SW10 may be disposed on the first side of the second sub-region H2 of the first tile region TR0. Accordingly, the first contact plugs CP10 disposed in the first switching region SW10 may be electrically connected to the first conductive lines CL10 in a sub-region that is relatively distant from the second switching region SW20 among the first conductive lines CL10 crossing the first tile region TR0 to drive them. In this embodiment, the first conductive lines CL10 connected to the first contact plugs CP10 may cross the second sub-region H2, which is a lower sub-region. According to this embodiment of the present invention, four first conductive lines CL10 crossing the lower sub-region of the corresponding tile region TR0 may cross the first switching region SW10.

In addition, the second tile region TR0 may be divided into two parts in the second direction. Each of the two parts may correspond to approximately half of the second tile region TR0. When the two parts correspond to a third sub-region H3 and a fourth sub-region H4, respectively, the third sub-region H3 may be closer to the second switching region SW20 compared to the fourth sub-region H4.

When the pair of first and second tile regions TR0, the second switching region SW20 disposed between the first and second tile regions TR0, and the first switching region SW10 disposed on the first side of the second sub-region H2 of the first tile region TR0 form one unit, the semiconductor device may include a plurality of units arranged in the first direction and/or the second direction.

Here, a plurality of pairs of tile regions TR0 that are arranged in the second direction may be aligned with each other. Although this embodiment of the present disclosure illustrates a case where two pairs of tile regions TR0 are arranged serially in the second direction, embodiments are not limited thereto, and the number of pairs arranged in the second direction may vary.

On the other hand, pairs of tile regions TR0 that are arranged in the first direction and the first switching region SW10 may not be aligned with each other. The first switching regions SW10 that are adjacent in the first direction may be arranged not to be aligned with each other in the second direction, but they form a staircase shape. To be specific, a plurality of pairs of tile regions TR0 may be arranged in the first direction such that a second sub-region H2 of a first pair (e.g., \textcircled{a}) is aligned with a fourth sub-region H4 of a second pair (e.g., \textcircled{b}), which is disposed on the first side of the first pair, and the remaining portions of the first pair excluding the second sub-region H2, that is, a first sub-region H1, a third sub-region H3, and a fourth sub-region H4 of the first pair, are aligned with some portions of a third pair (e.g., \textcircled{c}), which is disposed on the first side of the first pair, e.g., a first sub-region H1, a second sub-region H2, and a third sub-region H3 of the third pair. The second pair and the third pair are arranged in the second direction on the first side of the first pair.

The second conductive lines CL20 may be arranged to extend in the second direction and to be spaced apart from each other in the first direction. In the second direction, the second conductive lines CL20 may cross two tile regions TR0 and a second switching region SW20 disposed between the two tile regions TR0. Accordingly, the center of the second conductive lines CL20 may contact the second contact plugs CP20 in the second switching region SW20. When it is assumed that the length of one tile region TR0 in the second direction is 2b, the length of a portion of the second conductive line CL20 disposed on each of both sides of the second switching region SW20 may substantially correspond to 2b. Although it is illustrated in this embodiment that the number of second conductive lines CL20 crossing one tile region TR0 is 6, embodiments are not limited thereto, and the number of second conductive lines CL20 crossing one tile region TR0 may vary diversely.

The second contact plugs CP20 may be disposed in the second switching region SW20 to respectively contact the second conductive lines CL20 so that they are electrically connected to the second conductive lines CL20. Accordingly, the second contact plugs CP20 may be arranged in the first direction. The number of second contact plugs CP20 arranged in one second switching region SW20 may be the same as the number of second conductive lines CL20 crossing one tile region TR0. For example, when the number of second conductive lines CL20 crossing one tile region TR0 is six, six second contact plugs CP20 may be arranged in one second switching region SW20.

The first conductive lines CL10 may be arranged to extend in the first direction and to be spaced apart from each other in the second direction. In the first direction, the first conductive lines CL10 may cross the first switching region SW10 and tile regions TR0 disposed on each of both sides of the first switching region SW10. In other words, the first conductive line CL10 may cross four tile regions TR0 in the first direction, and the center of the first conductive line CL10 may contact the first contact plug CP10 disposed in the first switching region SW10. When it is assumed that the length of one tile region TR0 in the first direction is 2a, the length of a portion of the first conductive line CL10 disposed on each of both sides of the first switching region SW10 may substantially correspond to 4a. According to this embodiment of the present disclosure, the number of first conductive lines CL10 crossing one tile region TR0 is 8, but embodiments are not limited thereto. The number of first conductive lines CL10 crossing one tile region TR0 may vary diversely.

As described above, since the first switching region SW10 is disposed beside the second sub-region H2 of the corresponding tile region TR0, the number of first conductive lines CL10 crossing the first switching region SW10 may be half of the number of first conductive lines CL10 crossing one tile region TR0. For example, when the number of first conductive lines CL10 crossing one tile region TR0 is 8, the number of first conductive lines CL10 crossing the first switching region SW10 is 4.

According to this embodiment of the present disclosure, 2a and 2b may be different, and accordingly, the number of first conductive lines CL10 crossing one tile region TR0 and the number of second conductive lines CL20 crossing one tile region TR0 may be different, but embodiments are not limited thereto. According to another embodiment of the present disclosure, 2a and 2b may be substantially the same, and accordingly, the number of first conductive lines CL10 crossing one tile region TR0 may be the same as the number of second conductive lines CL20 crossing one tile region TR0.

The first contact plugs CP10 may be disposed in the first switching region SW10 to respectively contact the first conductive lines CL10 crossing the first switching region SW10 so that they are electrically connected to the first conductive lines CL10. Accordingly, the first contact plugs CP10 may be arranged in the second direction. The number of first contact plugs CP10 arranged in one first switching region SW10 may be the same as the number of first conductive lines CL10 crossing the second sub-region H2 of the corresponding tile region TR0. For example, when the number of first conductive lines CL10 crossing the corresponding tile region TR0 is 8, four first contact plugs CP10 may be arranged in one first switching region SW10.

The first contact plug CP10 and the second contact plug CP20 may be electrically connected to various driving circuits provided in the substrate (not shown) to supply the required voltage or current to the first conductive line CL10 and the second conductive line CL20.

The memory cells MC0 may be arranged to respectively overlap with the intersection regions between the first conductive lines CL10 and the second conductive lines CL20 in the form of a matrix in the first direction and the second direction in the tile region TR0. For example, in one tile region TR0, 48 memory cells MC0 may be arranged in a 6*8 form in the first direction and the second direction.

According to this embodiment of the present disclosure, since the length of the first conductive line CL10 that is driven by the first switching region SW10 is doubled compared to the embodiment described with reference to FIGS. 1A and 1B, it may be possible to drive all the first conductive lines CL10 after all. For example, the first conductive line CL10 crossing the second sub-region H2 of the first pair of tile regions TR0 (e.g., \textcircled{a}) may be coupled to the corresponding first switching region SW10 to be driven. The first conductive line CL10 crossing the first sub-region H1 of the first pair of tile regions TR0 (e.g., \textcircled{a}) may be coupled to a non-corresponding first switching region SW10, e.g., the first switching region SW10 disposed in the third pair of tile regions TR0 (e.g., \textcircled{c}), which is adjacent on the first side of the first pair of tile regions TR0 (e.g., \textcircled{a}), to be driven. Similarly, the first conductive line CL10 crossing the third sub-region H3 and the first conductive line CL10 crossing the fourth sub-region H4 in the first pair of tile regions TR0 (e.g., \textcircled{a}) may also be driven by different first switching regions SW10. In other words, the first conductive lines CL10 crossing the first sub-region H1, the second sub-region H2, the third sub-region H3, and the fourth sub-region H4 of one tile region TR0 may be driven by different first switching regions SW10, and among these first conductive lines CL10, only the first conductive line CL10 crossing the second sub-region H2 may be driven by the first switching region SW10 corresponding to the tile regions TR0 in the first pair of tile regions TR0 (e.g., \textcircled{a}).

Also, since the number of first switching regions SW10 and/or the area occupied by the first switching regions SW10 is substantially reduced compared to the above-described embodiment of the present disclosure described with reference to FIGS. 1A and 1B, it is possible to increase the integration degree of the semiconductor device.

Furthermore, according to the embodiment of the present disclosure, the distance from the first and second switching regions SW10 and SW20 to the near memory cells increases, and thus the difference between the distance between the first and second switching regions SW1 and SW2 and the near memory cells and the distance between the first and second switching regions SW1 and SW2 and the far memory cells is reduced. As a result, it is possible to prevent the occurrence of the excessive current flowing into the near memory cells. This will be illustratively explained with reference to FIG. 2C.

FIG. 2C numerically illustrates the distance from a switching region to a memory cell in the semiconductor device shown in FIGS. 2A and 2B. In particular, FIG. 2C illustrates the distance between memory cells and a switching region in a portion P1 of the semiconductor device shown in FIG. 2B.

Referring to FIG. 2C, the numbers may represent the distance from corresponding first and second switching regions SW10 and SW20 to each of 48 memory cells MC0 disposed in each tile region TR0. Here, the distance from the first and second switching regions SW10 and SW20 may correspond the sum of the distance from the first switching region SW10 in the first direction and the distance from the second switching region SW20 in the second direction. The distance from the first switching region SW10 to the memory cell MC0 coupled to the closest second conductive line CL20 in the first direction may be defined as 1, and the distance from the second switching region SW20 to the memory cell MC0 coupled to the closest first conductive line CL10 in the second direction may be defined as 1.

In this case, the minimum value of the distance between the memory cell MC0 and the first and second switching regions SW10 and SW20 may correspond to 1+5, that is, 6. In other words, the distance to the memory cell MC0 represented by N may correspond to 6. On the other hand, the maximum value of the distance between the memory cell MC0 and the first and second switching regions SW10 and SW20 may be 12+4, that is, 16. In other words, the distance to the memory cell MC0 represented by F may correspond to 16. Similarly, the distance from the first and second switching regions SW10 and SW20 to each of the memory cells MC0 may be calculated.

According to the embodiment described with reference to FIGS. 1B and 1G, the minimum value of the distance between the memory cell MC and the first and second switching regions SW1 and SW2 is 2. On the other hand, according to this embodiment shown in FIG. 2B, the minimum value of the distance between the memory cell MC0 and the first and second switching regions SW1 and SW2 may be greatly increased to 6. Therefore, it is possible to prevent and/or reduce the operation failure that may be caused due to the excessive current flowing into the near memory cell.

Furthermore, according to the embodiment described with reference to FIGS. 1B and 1G, since the minimum value of the distance between the memory cell MC and the first and second switching regions SW1 and SW2 is 2 and the maximum value of the distance between the memory cell MC and the first and second switching regions SW1 and SW2 is 14, the difference between them may be 12. On the other hand, according to this embodiment shown in FIG. 2B, since the minimum value of the distance between the memory cell MC0 and the first and second switching regions SW10 and SW20 is 6 and the maximum value of the distance between the memory cell MC0 and the first and second switching regions SW10 and SW20 is 16, the difference between them may be reduced to 10. Accordingly, the difference in the operation characteristics between the near memory cell and the far memory cell may be reduced, thereby improving the operation characteristics of the semiconductor device.

According to the embodiment shown in FIG. 2B, it is possible to prevent defects in near memory cells and reduce the difference in operation characteristics between near memory cells and far memory cells.

According to the embodiment shown in FIG. 2B, the degree of integration of the semiconductor device may be increased by reducing the number of switching regions.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a plurality of pairs of tile regions arranged in a first direction and a second direction crossing the first direction, each pair of tile regions including first and second tile regions with a second switching region interposed therebetween in the second direction;
a first switching region disposed on a first side of the first tile region in the first direction and disposed beside a second sub-region of the first tile region, the first tile region being divided into a first sub-region and the second sub-region in the second direction, the first sub-region being closer to the second switching region compared to the second sub-region;
a first conductive line extending in the first direction to cross the first switching region and tile regions disposed on each of both sides of the first switching region in the first direction, and electrically connected to the first switching region;
a second conductive line extending in the second direction to cross each pair of tile regions and the second switching region, and electrically connected to the second switching region; and
a memory cell disposed in an intersection region between the first conductive line and the second conductive line in a third direction that is perpendicular to the first and second directions.

2. The semiconductor device of claim 1, wherein when the second tile region is divided into a third sub-region and a fourth sub-region in the second direction, the third sub-region being closer to the second switching region compared to the fourth sub-region, no first switching region being beside each of the third and fourth sub-regions,
among the plurality of pairs of tile regions, a second sub-region of a first pair is aligned with a fourth sub-region of a second pair that is adjacent to the first pair on the first side of the first pair, and
a first sub-region, a third sub-region, and a fourth sub-region of the first pair are respectively aligned with a second sub-region, a first sub-region, and a third sub-region of a third pair that is adjacent to the first pair on the first side of the first pair,
wherein the second pair and the third pair are arranged in the second direction on the first side of the first pair.

3. The semiconductor device of claim 1, wherein, among the plurality of pairs of tile regions, pairs of tile regions arranged in the second direction are aligned with each other.

4. The semiconductor device of claim 1, wherein when the second tile region is divided into a third sub-region and a fourth sub-region in the second direction, the third sub-region being closer to the second switching region compared to the fourth sub-region, no first switching region being beside each of the third and fourth sub-regions,
a first conductive line crossing the second sub-region is electrically connected to the first switching region.

5. The semiconductor device of claim 4, wherein first conductive lines crossing the first sub-region, the third sub-region, and the fourth sub-region are electrically connected to first switching regions that are different from the first switching region electrically connected to the first conductive line crossing the second sub-region.

6. The semiconductor device of claim 1, wherein when the second tile region is divided into a third sub-region and a fourth sub-region in the second direction, the third sub-region being closer to the second switching region compared to the fourth sub-region, no first switching region being beside each of the third and fourth sub-regions,
the first conductive line crossing each of the first sub-region, the second sub-region, the third sub-region, and the fourth sub-region is electrically connected to different first switching regions.

7. The semiconductor device of claim 1, wherein the first switching region includes a first contact plug coupled to the first conductive line.

8. The semiconductor device of claim 7, wherein the first conductive line is disposed over a substrate, and
the first contact plug is disposed between the first conductive line and the substrate in the third direction and electrically connects the first conductive line and the substrate.

9. The semiconductor device of claim 1, wherein the second switching region includes a second contact plug coupled to the second conductive line.

10. The semiconductor device of claim 9, wherein the second conductive line is disposed over a substrate, and
the second contact plug is disposed between the second conductive line and the substrate in the third direction and electrically connects the second conductive line and the substrate.

11. The semiconductor device of claim 1, wherein the memory cell includes
a variable resistance layer that switches between different resistance states.

12. The semiconductor device of claim 1, wherein a sub-region corresponds to half of a tile region.

13. A semiconductor device, comprising:
first and second tile regions including a plurality of first conductive lines each extending in a first direction, a plurality of second conductive lines each extending in a second direction crossing the first direction, and a plurality of memory cells respectively overlapping with intersection regions between the first conductive lines and the second conductive lines, the first and second tile regions being disposed to be adjacent to each other in the second direction;
a second switching region disposed between the first tile region and the second tile region and coupled to the second conductive lines; and
a first switching region disposed on a first side of the first tile region in the first direction, and coupled to a first conductive line crossing a second sub-region of the first tile region, wherein the first tile region is divided into a first sub-region and the second sub-region in the second direction, the first sub-region being closer to the second switching region compared to the second sub-region.

14. The semiconductor device of claim 13, wherein the first conductive line crossing the second sub-region crosses the first switching region and tile regions disposed on each of both sides of the first switching region in the first direction.

15. The semiconductor device of claim 13, wherein the second conductive line crosses the first tile region and the second tile region.

16. The semiconductor device of claim 13, wherein the first switching region includes a first contact plug coupled to the first conductive line crossing the second sub-region.

17. The semiconductor device of claim 13, wherein the second switching region includes a second contact plug coupled to the second conductive line.

18. The semiconductor device of claim 13, wherein a sub-region corresponds to half of a tile region.
